(19) United States
(12) Patent Application Publication
(10) Pub. No.: US 2009/0199638 A1
(43) Pub. Date: Aug. 13, 2009

(54) Measuring physical quantities using resonant structures

(76) Inventors: Mark D. Jeffs, Oxfordshire (GB); James E. Gilkes, Oxfordshire (GB)

Correspondence Address: NIXON & VANDERHYE, PC, 901 NORTH GLEBE ROAD, 11TH FLOOR, ARLINGTON, VA, 22203, US

(21) Appl. No.: 11/919,550

(22) PCT Filed: May 2, 2006
(86) PCT No.: PCT/GB2006/001592

§ 371 Date: Oct. 30, 2007

(30) Foreign Application Priority Data
May 4, 2005 (GB) 0509113.7

(51) Int. Cl. G01R 27/26

(52) U.S. Cl. 73/579

(57) ABSTRACT

Apparatus and methods for measuring physical quantities making use of resonant structures, the resonant frequency of which changes with changes of the physical quantity. Techniques for detecting resonance are described. In one embodiment the apparatus comprises detecting circuit which has an arming circuit including a receiver which tracks the frequency of excitation signals and on the basis of the detected amplitude of the signals in that frequency range arms a comparator to compare signals indicative of the relative phase of the excitation signal and a signal reflected by the resonant structures which in turn allows resonance to be detected.

This invention relates to apparatus for use in measuring physical quantities by making use of electrically resonant structures whose properties are affected by the physical quantities to be measured. The invention relates to methods and apparatus for measuring physical quantities using such techniques and also to methods and apparatus which may be used in such techniques. That is to say the present invention not only relates to the overall process of measuring a physical quantity whilst making use of the idea of monitoring an electrically resonant structure whose behaviour changes with that physical quantity, but also to apparatus and methods which may be used to generate information or output which is indicative of the condition of the electrically resonant structure which may then be used by an external apparatus/separate method to give information concerning the value of the physical quantity.

The use of resonant structures, and in particular, SAW (surface acoustic wave) devices and STW (surface transverse wave) devices in the measurement of physical quantities is known. U.S. Pat. No. 5,585,571 and U.S. Pat. No. 6,237,417 are examples of documents which describe such ideas.

In the present invention use is made of the fact that electrically resonant structures such as SAW devices may be arranged so that the resonant frequency of the structure is affected by a physical quantity in a repeatable way such that if the resonant frequency of the resonant structure is monitored it becomes possible to also monitor the physical quantity of interest. Physical quantities which may be monitored in this way include strain for example rotational strain or torque, temperature and pressure. Particular configurations of SAW devices may be used in measuring such quantities. This is explained for example in U.S. Pat. No. 5,585,571.

Whilst systems using the principles of U.S. Pat. No. 5,585,571 and U.S. Pat. No. 6,237,417 can and have been constructed and used, it is desirable to facilitate the manufacture of apparatus for monitoring the value of physical quantities which can provide an enhanced level of performance. It is also preferable if such apparatus may be relatively small and cost effective.

It is an object of the present invention to provide apparatus and methods which are intended to facilitate the goal of maximising performance of apparatus for measuring physical quantities and for use in measuring physical quantities whilst preferably enabling the production of relatively small and cost effective apparatus.

According to one aspect of the invention there is provided an apparatus for use in measuring the value of at least one physical quantity, the apparatus comprising at least one electrically resonant structure, the resonant frequency of which is affected by said physical quantity, an electrical energy source, and a transmission line connecting the source to the resonant structure, wherein the electrical energy source is arranged to provide excitation signals to the electrically resonant structure via the transmission line and is controllable so as to vary the frequency of applied excitation signals, the apparatus further comprising detecting means for monitoring signals on the transmission line following application of excitation signals, the detecting means being arranged to output an indicator signal if a frequency is determined, from monitoring the detected signal, to be representative of the then current resonant frequency of the electrically resonant structure.

The detecting means may be arranged for monitoring reflected signals returned along the transmission line from the resonant structure.

For the avoidance of doubt it is mentioned that the term “current” resonant frequency is used to refer to the resonant frequency existing at that time and in no way should be taken to suggest a resonant frequency which is particularly related to electrical “current”.

The frequency associated with the indicator signal may be a frequency of an applied excitation signal. The frequency associated with the indicator signal may be a calculated frequency.

The detecting means may comprise a directional coupler. The detecting means may be arranged for detecting the amplitude of the detected signal. The detecting means may be arranged for detecting the voltage of the detected signal.

The detecting means may comprise decision means for deciding whether a frequency of an applied excitation signal is representative of the then current resonant frequency of the resonant structure. The detecting means may comprise calculation means for calculating a frequency which is representative of the then current resonant frequency.

The apparatus may be arranged so that the amplitude of the reflected signals goes through a minimum as the frequency of the excitation signal goes through the resonant frequency of the resonant structure.

The detecting means may be arranged for detecting the phase of the reflected signal. The apparatus may be arranged so that the phase of the reflected signal goes through a transition as the frequency of the excitation signal goes through the resonant frequency of the resonant structure. The phase of the reflected signal may lead the phase of the excitation signal while the frequency of the excitation signal is on one side of the resonant frequency and lag the phase of the excitation signal while the frequency of the excitation signal is on the other side of the resonant frequency. The phase response may differ in dependence on whether the frequency of the applied signals is increased through resonance or decreased through resonance.

The detecting means may comprise arming means for controllably arming the decision means or calculation means such as to enable decision making or calculation. The arming means may be arranged to detect the amplitude of the reflected signal and arm the decision means or calculation means if a predetermined amplitude threshold condition is satisfied. The arming means may be arranged to inhibit operation of the decision means or calculation means when the applied signal is not in a frequency range corresponding to the resonant structure response.

In one set of embodiments the decision means is arranged to monitor the phase of the reflected signal to decide whether a frequency of an applied excitation signal is representative of the then current resonant frequency of the resonant structure, whilst the arming means is arranged to arm the decision means to enable such a decision only if a predetermined amplitude threshold condition is satisfied.

In another set of embodiments the decision means is arranged to monitor the amplitude of the detected signal to decide whether a frequency of an applied excitation signal is representative of the then current resonant frequency of the resonant structure, and the arming means is arranged to arm the decision means to enable such a decision only if a predetermined amplitude threshold condition is satisfied.

The detecting means may be arranged to generate an in phase signal using the reflected signal and a quadrature phase signal using the reflected signal. The in phase signal and quadrature phase signal may be generated using the same derived reflected signal. The decision means may be arranged for comparing the quadrature phase signal with the in phase signal in determining whether a frequency of an applied excitation signal is representative of the then current resonant frequency of the resonant structure.

The decision means may be arranged to determine that a frequency of an applied excitation signal is representative of the then current resonant frequency of the resonant structure when the frequency of the applied excitation signal is such that it is detected that the quadrature phase signal crosses with the in phase signal.

The decision means may be arranged to perform a curve fitting operation on the detected signal as the frequency of applied excitation signals is changed in order to determine when a frequency of an applied excitation signal is representative of the then current resonant frequency of the resonant structure. The calculation means may be arranged to perform a curve fitting operation. Where the apparatus is arranged so that the amplitude of the detected signals approaches a turning point, in particular a minimum, as the frequency of the excitation signal approaches the resonant frequency of the resonant structure, the curve fitting operation may be arranged to identify the turning point, in particular the minimum. The curve fitting operation may comprise the steps of determining the two frequencies, one on each side of the turning point, of the applied excitation signal at which the detected signal passes a first predetermined value in amplitude; determining the two frequencies, one on each side of the turning point, of the applied excitation signal at which the detected signal passes a second predetermined value in amplitude; fitting a first straight line to the two points so determined on a first side of the turning point; fitting a second straight line to the two points so determined on a second side of the turning point; and determining the frequency of applied excitation signal which corresponds to the point where these two straight lines cross one another.

The decision means may be arranged to use a Kalman filter in determining whether a frequency of an applied excitation signal is representative of the then current resonant frequency. The calculation means may use a Kalman filter.

The decision means may be arranged to identify a turning point in the amplitude of the detected signal as the frequency of applied excitation signals is varied. The frequency at which a turning point is detected may be used as the representative frequency. The decision means may comprise a valley point detection means. It is particularly preferred if an arming means of the type defined above is used where the decision means is arranged to identify turning points. This is to help avoid false readings.

The decision means may comprise delay means for applying a delay to the detected signal as received by the decision means to generate a delayed signal. The delay means may be arranged so that the delayed signal has substantially the same maximum and minimum magnitude as the received signal. The decision means may be arranged to compare the delayed signal and the detected signal as received. The delayed signal will follow the received signal and the decision means may be arranged so that, away from any turning point, while the received signal is rising, the delayed signal is less than the received signal, whereas while the received signal is falling, the delayed signal is greater than the received signal. In this way when a turning point in the received signal is reached, the relative magnitudes of the received signal and delayed signal will switch, after a delay. This switch may be detected by comparing the two signals and the frequency of applied signal at which this switch is detected may be determined as the representative frequency. Analog circuit components for example, a capacitor and resistor may be provided to detect this switch. Digital means may be provided to detect the switch, for example a analog to digital sampling circuit and a micro-computer.

The detecting means may comprise a tracking tuned receiver means which is arranged to track the frequency of the applied excitation signals. This can diminish the effect of signals present on the transmission line which are away from the frequency of the applied excitation signal at any one point in time.

The tracking tuned receiver means may be arranged to mix a signal derived from the applied excitation signal with the detected signal to generate a signal for further processing. The signal for further processing may comprise the difference signal (the signal having the heterodyne frequency) generated in said mixing process. The signal for further processing may be filtered to provide a filtered signal which is for further processing.

The tracking tuned receiver means may be arranged to generate the signal derived from the applied excitation signal by mixing the applied excitation signal with a signal from a local oscillator having a predetermined frequency. The signal derived from the applied excitation signal may comprise the difference signal (the signal having the heterodyne frequency) generated in said mixing process.

The tracking tuned receiver means and electrical energy source may be disposed physically close to one another, they may for example be provided on the same integrated circuit chip. There may be direct electrical contact between the tracking tuned receiver means and electrical energy source.

The apparatus may comprise a plurality of electrically resonant structures. The electrically resonant structures may be connected in parallel to the transmission line.

Typically, each resonant structure will have a distinct resonant frequency under a given set of prevailing conditions, this may be termed a default resonant frequency for the respective structure. The spacing in resonant frequency between such a plurality of structures may be chosen so that, the resonant frequency of each structure will be independently determinable under all normal operating conditions of the apparatus.

The apparatus may be arranged so that the detecting means will output a respective indicator signal when the frequency of an applied excitation signal is representative of the then current resonant frequency of each respective one of the plurality of electrically resonant structures.

The apparatus may be arranged for connection to external analysing means arranged to use the output of the apparatus to measure the value of a physical quantity.

The apparatus may comprise analysing means and hence be arranged for measuring the value of a physical quantity.

In some instances the apparatus may be arranged so that the frequency which is determined representative of the then current resonant frequency will be very close to, or in practical terms the same as, the then current resonant frequency.

In other instances the apparatus may be arranged so that the frequency which is determined representative of the then current resonant frequency is different from but has a predetermined relationship to the then current resonant frequency. The predetermined relationship may be known in absolute terms, or be known to be the same or substantially the same for a plurality of resonant structures present in an apparatus. In some such instances, there may be a significant difference between the representative frequency and the then current resonant frequency. However, by using a compensation technique, for example, by taking an offset (if known/determinable) into account, and/or by calibration and/or by using a differencing method, the resolution of the apparatus need not be adversely affected by such a difference.

In some instances the difference may vary in time, but provided that such variations are not too great, useful measurements can be made. Multiple readings can, of course, be used to improve accuracy.

In some cases the identified frequency may be used directly, for example, by the analysing means, to give a value for the physical quantity which is being measured. Thus, for example, in a simple system where there is a single resonant structure and a single physical quantity to be measured, say temperature, a direct temperature reading may be taken using the frequency determined as representative of resonant frequency. Of course multiple readings might be taken to improve accuracy.

Where there is more than one resonant structure in the apparatus, the determined representative frequency may be used in a differencing method. The analysing means may be arranged to use a differencing method. The apparatus may be arranged so that the value of the physical quantity to be measured is related to a difference in resonant frequency between two resonant structures provided in the apparatus. Such a set up is an example of using a differencing method.

Differencing methods may also be used where it is a change in resonant frequency of the resonant structure which is indicative of a physical quality, again in this situation offsets can cancel with one another.

It will be appreciated that in some embodiments the actual resonant frequency may never be determined but rather a difference in resonant frequency indicated by two indicator signals used to determine the value of a physical quantity.

When an apparatus is initiated, the resonant frequency of the or each resonant structure under default conditions may not be accurately known. As an initiation step the resonant frequency of the or each resonant structure under default conditions may be determined, for example to ascertain initial zero conditions without strain applied.

The electrical energy source may be arranged to frequency sweep the excitation signals. The frequency sweep may take the form of continuously applying and discretely or continuously varying the frequency of excitation signal. The frequency sweep may take the form of applying discrete pulses of excitation signal and changing the frequency between pulses.

The apparatus may be arranged to apply excitation signals by sweeping the frequency of the signals over an entire range within which the or each resonant structure may be expected to be caused to resonate. A complete sweep may be conducted, for example, in the initiation step mentioned above.

The apparatus may be arranged to apply excitation signals by sweeping the frequency of the signals over at least one selected range of frequencies around a trial resonant frequency of at least one resonant structure. This can avoid the need to sweep the frequency across the entire operational range of the apparatus in each operation. The apparatus can be made to miss out parts of the frequency range by “jumping” from looking for the resonant frequency of one resonant structure to looking for the resonant frequency of another resonant structure. This can increase processing speed.

The trial resonant frequency may be set equal to the default resonant frequency. The trial resonant frequency may be set equal to the resonant frequency for that resonant structure as last detected. The trial resonant frequency may be calculated taking into account the measured resonant frequency of another resonant structure which has been more recently determined. The calculation may also make use of the value of the default resonant frequency.

Where the technique of sweeping across only selected ranges of frequencies is used, the energy source may be arranged so that the amplitude of the applied signals at the start of each range is reduced relative to the average amplitude. This means the signals can ramp up to full magnitude and can help to avoid undesirable effects which can occur due to the additional, high frequency, signal components associated with sharp edged pulses. Where discrete pulses are used, a selected number of pulses at the beginning of the range can be given reduced amplitude.

The effects at the end of the range are of less concern as a measurement will have been taken by this time, but the amplitude at the end of the range can also be trailed off.

The apparatus may comprise an integrated circuit chip.

The or each resonant structure may have an impedance which varies continuously as a function of the value of the physical quantity. The or each resonant structure may comprise a piece of piezo-electric material. The or each resonant structure may comprise an acoustic wave device, such as, but not limited to a SAW (Surface Acoustic Wave) device or a STW (Surface Transverse Wave) device. The or each resonant structure may comprise amorphous wire.

Typically the resonant structure is substantially non energy radiating.

According to another aspect of the present invention there is provided a method of using an apparatus in measuring the value of at least one physical quantity, the apparatus comprising at least one electrically resonant structure, the resonant frequency of which is affected by said physical quantity, an electrical energy source, and a transmission line connecting the source to the resonant structure, and the method comprising the steps of:

using the electrical energy source to provide excitation signals to the electrically resonant structure via the transmission line and controllably varying the frequency of applied excitation signals;

monitoring signals on the transmission line following application of excitation signals; and outputting an indicator signal if a frequency is determined to be representative of the then current resonant frequency of the electrically resonant structure.

The step of monitoring signals on the transmission line preferably comprises the step of monitoring reflected signals returned along the transmission line from the resonant structure.

The method may comprise further steps which correspond generally to the further optional features of the invention defined following the first aspect of the invention above. The corresponding method steps are not restated in full here in the interests of brevity. Similarly the methods may be conducted using an apparatus having any one of, or any combination of the above optional features.

According to another aspect of the present invention there is provided apparatus for use in measuring the value of at least one physical quantity, the apparatus comprising at least one electrically resonant structure, the resonant frequency of which is affected by said physical quantity, an electrical energy source, and a transmission line connecting the source to the resonant structure, wherein the electrical energy source is arranged to provide excitation signals to the electrically resonant structure via the transmission line and is controllable so as to vary the frequency of applied excitation signals, the apparatus further comprising a detection module for monitoring signals on the transmission line following application of excitation signals, the detection module being arranged to output an indicator signal if a frequency is determined, from monitoring the detected signal, to be representative of the then current resonant frequency of the electrically resonant structure.

According to another aspect of the present invention there is provided apparatus for use in measuring the value of at least one physical quantity, the apparatus comprising at least one electrically resonant structure, the resonant frequency of which is affected by said physical quantity, an electrical energy source, and a bidirectional transmission line connecting the source to the resonant structure, wherein the electrical energy source is arranged to provide excitation signals to the electrically resonant structure via the transmission line and is controllable so as to vary the frequency of applied excitation signals, the apparatus further comprising a detection module for monitoring reflected signals returned along the transmission line from the resonant structure following application of excitation signals, the detection module being arranged to output an indicator signal if a frequency is determined, from monitoring the returned signal, to be representative of the then current resonant frequency of the electrically resonant structure.

According to another aspect of the present invention there is provided apparatus for use in measuring the value of at least one physical quantity, the apparatus comprising at least one electrically resonant structure, the resonant frequency of which is affected by said physical quantity, an electrical energy source, and a transmission line connecting the source to the resonant structure, wherein the electrical energy source is arranged to provide excitation signals to the electrically resonant structure via the transmission line and is controllable so as to vary the frequency of applied excitation signals, the apparatus further comprising a detection module for monitoring reflected signals returned along the transmission line from the resonant structure following application of excitation signals, the detection module being arranged to output an indicator signal if it is determined from monitoring the returned signal that a frequency of an applied excitation signal is representative of the then current resonant frequency of the electrically resonant structure, and wherein the detection module comprises a decision module for deciding whether the frequency of the applied excitation signal is representative of the then current resonant frequency of the electrically resonant structure and an arming module arranged to detect the amplitude of the reflected signal and arm the decision module if a predetermined amplitude threshold condition is satisfied, to enable operation of the decision module.

According to another aspect of the present invention there is provided apparatus for use in measuring the value of at least one physical quantity, the apparatus comprising at least one electrically resonant structure, the resonant frequency of which is affected by said physical quantity, an electrical energy source, and a transmission line connecting the source to the resonant structure, wherein the electrical energy source is arranged to provide excitation signals to the electrically resonant structure via the transmission line and is controllable so as to vary the frequency of applied excitation signals, the apparatus further comprising a detection module for monitoring reflected signals returned along the transmission line from the resonant structure following application of excitation signals, the detection module being arranged to output an indicator signal if it is determined from monitoring the returned signal that a frequency of an applied excitation signal is representative of the then current resonant frequency of the electrically resonant structure, and wherein the detection module is arranged to generate an in phase signal using the reflected signal and a quadrature phase signal using the reflected signal, the detection module comprises a decision module for deciding whether the frequency of the applied excitation signal is representative of the then current resonant frequency of the electrically resonant structure, and the decision module is arranged for comparing the quadrature phase signal with the in phase signal and arranged to determine that a frequency of an applied excitation signal is representative of the then current resonant frequency of the resonant structure when the frequency of the applied excitation signal is such that it is detected that the quadrature phase signal crosses with the in phase signal.

According to another aspect of the present invention there is provided apparatus for use in measuring the value of at least one physical quantity, the apparatus comprising at least one electrically resonant structure, the resonant frequency of which is affected by said physical quantity, an electrical energy source, and a transmission line connecting the source to the resonant structure, wherein the electrical energy source is arranged to provide excitation signals to the electrically resonant structure via the transmission line and is controllable so as to vary the frequency of applied excitation signals, the apparatus further comprising a detection module for monitoring reflected signals returned along the transmission line from the resonant structure following application of excitation signals, the detection module being arranged to output an indicator signal if a frequency is determined, from monitoring the returned signal, to be representative of the then current resonant frequency of the electrically resonant structure, and wherein the detection module comprises a calculation module for performing a curve fitting operation on the reflected signal as the frequency of applied excitation signals is changed in order to determine a frequency representative of the then current resonant frequency of the resonant structure.

According to another aspect of the present invention there is provided apparatus for use in measuring the value of at least one physical quantity, the apparatus comprising at least one electrically resonant structure, the resonant frequency of which is affected by said physical quantity, an electrical energy source, and a transmission line connecting the source to the resonant structure, wherein the electrical energy source is arranged to provide excitation signals to the electrically resonant structure via the transmission line and is controllable so as to vary the frequency of applied excitation signals, the apparatus further comprising a detection module for monitoring reflected signals returned along the transmission line from the resonant structure following application of excitation signals, the detection module being arranged to output an indicator signal if a frequency is determined, from monitoring the returned signal, to be representative of the then current resonant frequency of the electrically resonant structure, and wherein the detection module comprises a tracking tuned receiver which is arranged to track the frequency of the applied excitation signals.

According to another aspect of the invention there is provided a physical quantity measuring apparatus comprising an apparatus for use in measuring the value of at least one physical quantity as defined above.

Embodiments of the present invention will now be described by way of example only with reference to the accompanying drawings in which:

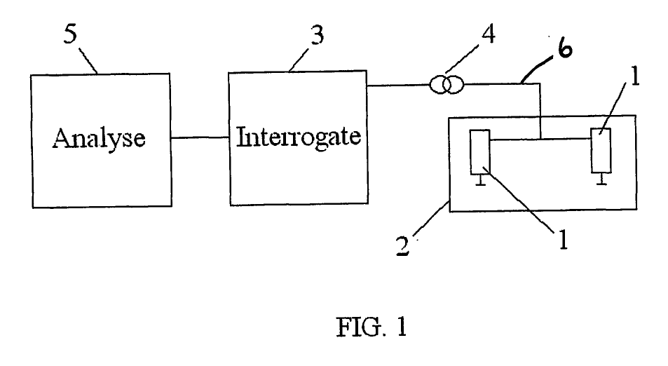

FIG. 1 schematically shows an apparatus for measuring the value of at least one physical quantity;

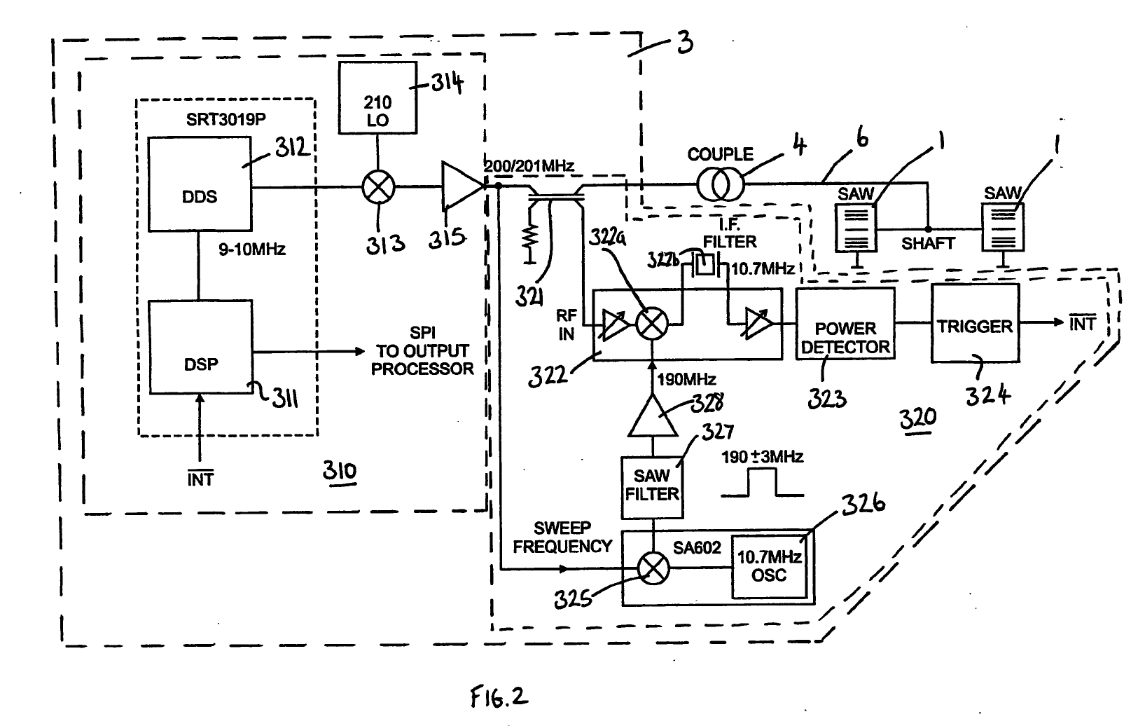

FIG. 2 shows more detail of part of the apparatus shown in FIG. 1;

FIG. 3 shows a valley detector circuit of the apparatus shown in FIGS. 1 and 2;

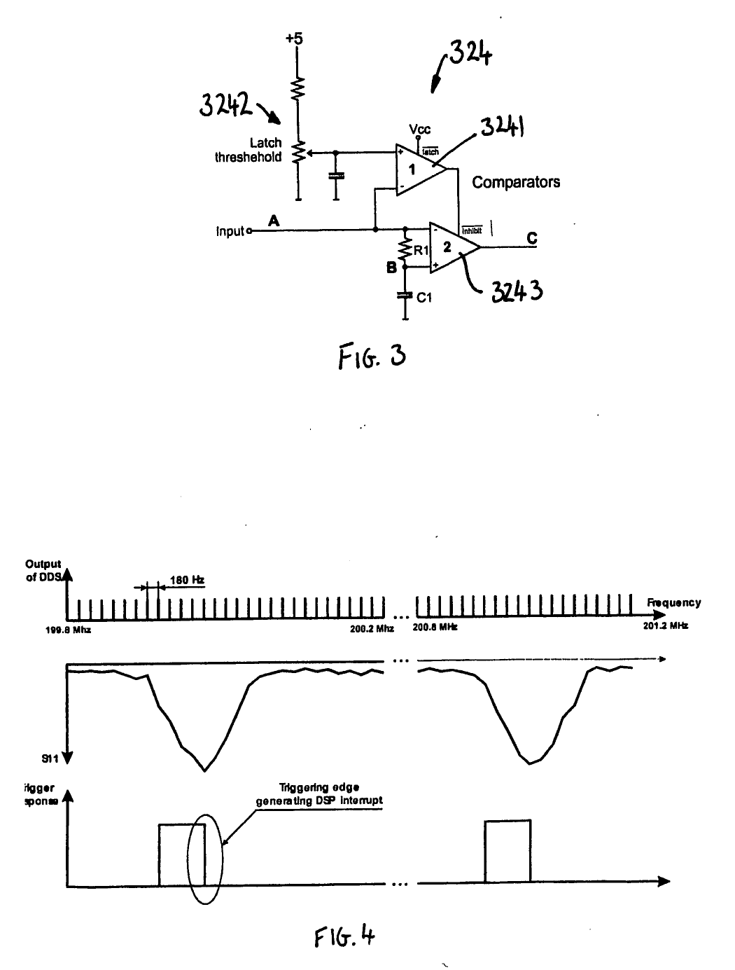

FIG. 4 is a diagram useful in explaining the operation of the valley detection circuit shown in FIG. 3;

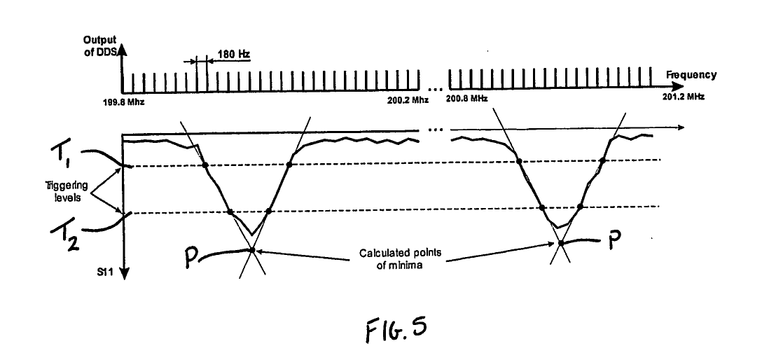

FIG. 5 is a diagram useful in explaining an alternative technique which can be used in place of using the valley detection circuit shown in FIG. 3;

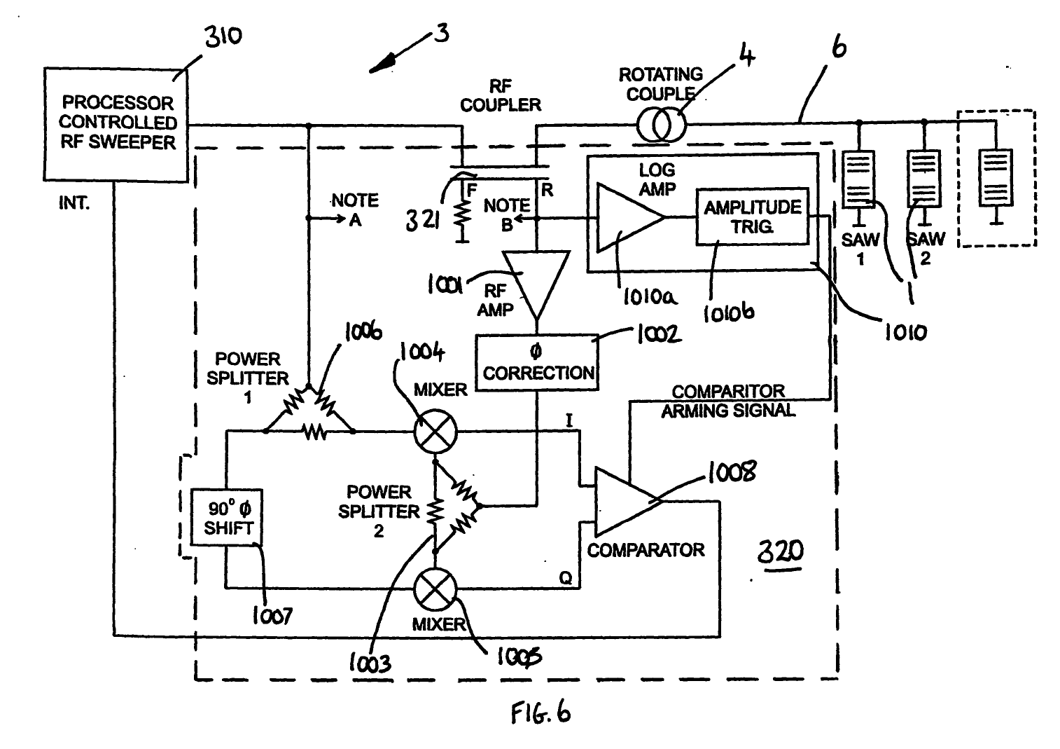

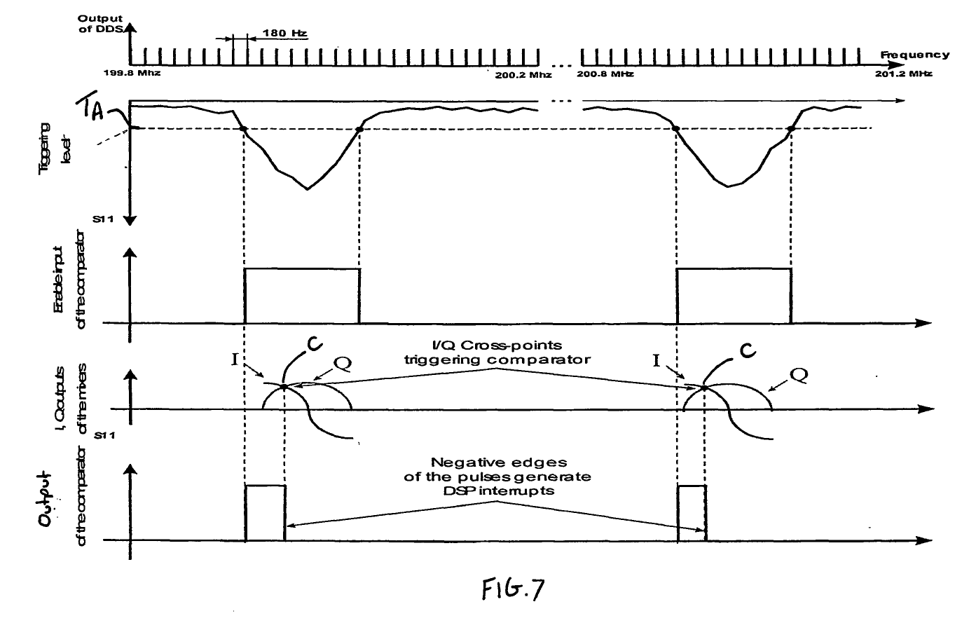

FIG. 6 shows part of an alternative apparatus for use in giving the value of at least one physical quantity which may be used as part of the apparatus shown in FIG. 1;

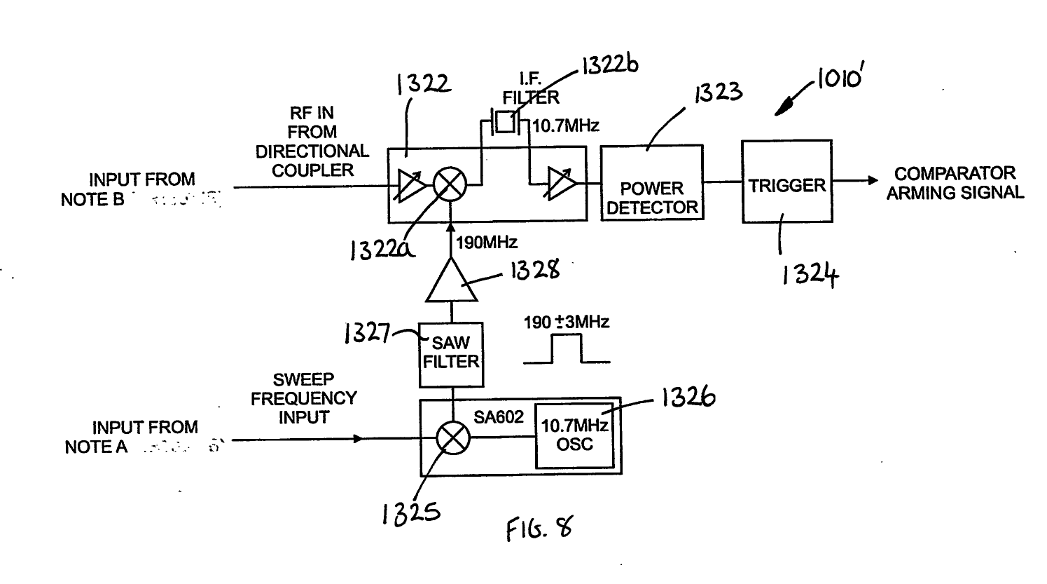

FIG. 7 shows a diagram which is useful in explaining the operation of the apparatus shown in FIG. 5; and

FIG. 8 schematically shows an alternative circuit which may be used in place of part of the apparatus shown in FIG. 6.

FIG. 1 schematically shows an apparatus for measuring the value of at least one physical quantity, for example torque, temperature, pressure or so on. In FIG. 1 the apparatus is shown at a general level and at this general level the apparatus comprises a plurality, in this case two, of electrically resonant structures which in this embodiment each comprises a respective SAW device 1. Each SAW device 1 is mounted to structure 2 in the location at which the physical quantity is to be measured. In the case of torque measurement, the structure 2 might be a shaft in respect of which it is desired to measure the rotational strain, i.e. torque being experienced by the shaft. The arrangement and mounting of the SAW devices 1 on the structure 2 is not particularly pertinent to the subject matter of the present specification and therefore further description of these aspects is omitted. Consideration of these factors can be found for example in U.S. Pat. No. 5,585,571.

The apparatus for measuring the physical quantity, further comprises interrogation apparatus 3 which in this embodiment is connected via a bi-directional RF transmission line 6 including a rotary couple 4 to the SAW devices 1. In alternatives, however, the connection between the interrogation apparatus 3 and the SAW devices I may be via a transmission line 6 of different constitution. In a particular example, the interrogation apparatus 3 may be provided with a suitable antenna arrangement and the SAW devices 1 provided with a suitable antenna arrangement so that signalling through free space between the interrogation apparatus 3 and the SAW devices 1 may be achieved.

In this embodiment, in addition to the interrogation apparatus 3, there is provided analysing apparatus 5 for analysing the output of the interrogation apparatus 3 and using this output to determine values for the or each physical quantity which is to be measured.

Thus, in basic operation the interrogation apparatus 3 applies signals to the SAW devices 1 and as a result of the application of these signals, detected signals are received at the interrogation apparatus 3 as will be explained in more detail below. These detected signals are dependent on the state of the SAW devices 1 and hence also dependant on the physical quantities or quantity which are/is to be measured. Within the interrogation apparatus 3, the received signals are processed and an output signal is fed from the interrogation apparatus to the analysing apparatus 5 where that output is used to determine the value for the or each physical quantity which is to be measured.

The structure and operation of the apparatus shown in FIG. 1 will be described in more detail below, but at this point it is worth noting that in at least some implementations, all of the component parts of the interrogation apparatus 3 may be provided on an integrated circuit chip. Furthermore, though in the present embodiment the analysing apparatus 5 is separate from the interrogation apparatus 3 and is constituted by software running on a general purpose computer, in other embodiments the analysing apparatus 5 may also comprise a dedicated integrated circuit chip and indeed there may be provided one integrated circuit chip which performs the functions of both the interrogation apparatus 3 and the analysing apparatus 5.

The use of integrated circuit chips for performing the functions of the interrogation apparatus 3 and/or analysing apparatus 5 can bring benefits in terms of reducing the size and cost of the necessary hardware for measuring the value of physical quantities using the current techniques. However, in order to achieve satisfactory performance, in at least some circumstances, it can be important to take steps which take into account the fact that the sensitivity of components provided in an integrated circuit chip and/or the cleanness of signals which may be generated within an integrated circuit chip cannot approach those which can be provided for by larger and more expensive apparatus.

It will of course be appreciated that whilst the use of integrated circuit chips is preferred, their use is not essential when carrying out the methods and apparatus of the present specification. That is to say the apparatus which are described below may be implemented without using integrated circuit chips or using a plurality of integrated circuit chips in combination with one another or in combination with other components.

FIG. 2 shows the interrogation apparatus 3 of FIG. 1 in more detail as well as showing this connected via the transmission line 6 to the two SAW devices 1. These three general elements, i.e. the interrogation apparatus 3, transmission line 6 and SAW devices 1 can be considered to make up apparatus for use in measuring the value of at least one physical quantity. It will be seen that these components together can be used as an apparatus in measuring the value of the physical quantity and facilitate the measurement of such a physical quantity, in this case by feeding an output signal to the analysing apparatus 5 as shown in FIG. 1.

At a general level the interrogation apparatus 3 shown in FIG. 2 comprises an RF electrical energy source 310 which is connected via the transmission line 6 including the couple 4, to the SAW devices 1 and a detection circuit 320 for detecting signals detected back along the transmission line 6 from the SAW devices 1. Again at a general level the principle of operation of the apparatus shown in FIG. 2 can be described as follows. The electrical energy source 310 delivers excitation signals to the SAW devices 1 via the transmission line 6. These SAW devices consist of two interdigitated arrays of electrodes positioned on a piece of piezo-electric material as is conventional. One of these sets of electrodes is connected to the transmission line 6 where the other set of electrodes is connected to ground. This means that each SAW device 1 acts as an impedance at the end of the transmission line 6. If there was perfect impedance matching then all of the energy delivered by the RF energy source 310 would be absorbed by the SAW devices 1 and there would be no reflection back along the transmission line 6. However, in practice there will be an impedance mis-match and signals will be reflected back along the transmission line 6. The nature of these reflected signals however will vary with the frequency of the applied signals and vary with the characteristics of the SAW devices 1. In particular, if the excitation signals provided by the source 310 are close or equal to the resonant frequency of one of the SAW devices 1 a greater degree of the excitation signal will be absorbed and a smaller reflection will be observed. Thus, at a basic level if this reflected signal can be monitored and detected it can be used to provide an indication that the excitation signal applied to the source is at or close to the resonant frequency of one of the SAW devices 1. This of course allows conclusions to be made about the then current resonant frequency of one of the SAW devices 1. In particular, if such a dip in amplitude is detected then the frequency of the applied excitation signal at which this occurs can be considered to be representative of the resonant frequency of that SAW at that point in time. Where there is more than one SAW device 1, as in the present embodiment, the resonant frequency of each SAW device 1 under a default condition (for example at a standard temperature and when not under any strain) can be chosen to be spaced from the resonant frequency of the other SAW device 1 or each other SAW device 1. Thus, in principle it becomes possible to independently determine the frequency of a plurality of SAW devices I using this interrogation technique.

Provided the apparatus, and in particular the SAW devices 1 are arranged appropriately, it is possible to ensure that the resonant frequency of each SAW device changes in a repeatable way and proportionally to a physical quantity of interest and thus if the resonant frequencies can be determined, the value of the physical quantity can also be determined.

The spacing in resonant frequency between each SAW device used (however many there are) may be chosen to ensure that during normal operation, i.e. covering the range of values of the physical quantities which are to be measured, no two SAW devices 1 will ever have the same resonant frequency. That is to say putting it colloquially, enough clear water may be left between each SAW device that it is always possible to independently determine the resonant frequency of each SAW device and be sure in the knowledge that when the resonant frequency has been determined that it can only relate to a particular SAW device 1 and none of the others.

SAW devices can be fabricated with different orders of resonant frequency. In one practical implementation tested by the applicants, SAW devices having a resonant frequency of around 200 MHz were used and a spacing in terms of resonant frequency, under default conditions, of 1 MHz was used. This system related to a torsional strain gauge where a measured strain of 500 micro-strain gave rise to a 100 KHz change in resonant frequency of the appropriate SAWS. With a 1 MHz separation between the resonant frequency of each SAW, it can be seen that a 100 KHz change does not threaten overlap. Another possible class of SAW device which could be used in such implementations have resonant frequencies of the order of 2.4 GHz and suitable separations between resonant frequencies when using such SAWs can easily be determined.

More description will now be given of the component parts of the apparatus shown in FIG. 2.

The RF energy source 310 is arranged to sweep the frequency of the excitation signals applied to the SAW devices 1 via the transmission line 6. In particular, it is arranged to sweep the frequency of the applied signals over the range necessary to cover the anticipated resonant frequency of each of the SAW devices 1.

At a simplest level of operation, each time a measurement is to be made, the RF energy source 310 can be arranged to sweep over the entire frequency range within which the resonant frequencies of the SAW devices 1 may fall. However, more sophisticated schemes may be implemented in order to reduce processing time. In one such scheme when the apparatus is first initialised then a complete sweep may be made to identify the precise resonant frequency of each SAW device 1 under default conditions (these default resonant frequencies may not be known exactly until such a measurement is made). Once this measurement has been made of the default resonant frequencies, when it is necessary to make an actual measurement of the physical quantity of interest, the RF energy source 310 may be arranged to first of all sweep the frequency of the excitation signals through a range which is in the region of the default resonant frequency of the first SAW device and then jump to a range which is in the region of the resonant frequency of the next SAW device 1. Thus, for example if there is a nominal 1 MHz separation in resonant frequency between each SAW device and under normal operating conditions, the frequency of each SAW device will vary by up to 100 KHz either side of the default resonant frequency, it can be seen that a 300 KHZ sweeping range could be centred on the default resonant frequency of the first SAW device 1 and then a jump made to a 300 KHz range centred on the default resonant frequency of a second SAW device 1. If this pattern is followed then the time taken to sweep through 700 KHz (1 MHz−150 KHz−150 KHz) worth of frequencies is saved by having made this jump.

These ideas can be extended further. When during a given measurement, the resonant frequency of a first of the SAW devices 1 has been measured, it may be possible to predict the likely resonant frequency of the next SAW device 1 to be interrogated. For example, in a typical method for measuring torsional strain, two SAW devices are arranged at 90° to one another and when the object being studied is placed under torsional strain, the resonant frequency of one of the SAW devices 1 will tend to increase whereas the resonant frequency of the other SAW device 1 will tend to decrease. Thus, if it is known that the resonant frequency of the first SAW device has increased relative to its default value then it can be predicted that the resonant frequency of the other SAW device 1 will have decreased relative to its default value. Predictions of this type can allow an even smaller range of frequencies to be swept in determining the actual resonant frequency of each SAW device 1 at that point in time.

In another development it is possible to focus in on the resonant frequency to obtain an accurate result more quickly. That is to say, a first quick scan (frequency sweep) might be completed to determine roughly the current resonant frequency of a given SAW device 1 and then a slower, more accurate scan completed, to more precisely identify the resonant frequency of that SAW device 1. This “focusing in” strategy is particularly pertinent where the electrical energy source 310 is arranged to apply discrete pulses of successively increasing/decreasing frequency through the transmission line 6 to excite the SAW devices. This mode of operation is used in the present embodiment as will be explained in more detail below.

The RF electrical energy source 310 comprises a digital signal processor (DSP) 311 which commands a direct digital synthesizer (DDS) 312 which generates continuous signals which change in frequency in a series of steps (note that the lines shown in FIGS. 4, 5 and 7—described below—indicate the frequency steps rather than indicating the transmission of pulses. There is no switching off of the signals between frequencies in this embodiment). In the present embodiment the frequency of each step is spaced by 180 Hz from the preceding step although of course any suitable step value may be chosen. The output of the direct digital synthesizer 312 consists of signals in the range of 9 to 10 MHz. In order to generate signals of the required frequency to excite the SAW devices 1 which in this case have resonant frequencies of around 200 MHz, the output of the direct digital synthesizer 312 is mixed in a mixer 313 with a signal from a local oscillator 314 which generates a signal at 210 MHz. This results in the output of the direct digital synthesizer 312 being upconverted to the required frequencies in the range of 200 MHz, of course, still with a 180 Hz step between each pulse. This upconverted signal is then fed to an amplifier 315 before being applied to the transmission line 6. Reference can be made to the upper plot in FIG. 4 which shows 180 Hz frequency spacing of the steps in the output of the electrical energy source 310.

The detection circuit 320 comprises a directional coupler 321 which has its forward terminal connected to ground through an impedance matching resistor and is thus arranged to detect the signal detected by the SAW devices 1 along the transmission line 6. The reflection port of the directional coupler 321 is connected to a receiver 322 and in turn the output of the receiver 322 is connected to a power detector 323. The output of the power detector 323 is connected to the trigger circuit 324 which is arranged as a decision module for determining when the frequency of a signal applied to the SAW devices 1 by the electrical energy source 310 is representative of the resonant frequency of one of the SAW devices 1.

The receiver 322 is arranged as a tracking receiver which remains tuned to the frequency of the excitation signals which are being applied to the transmission line 6 by the electrical energy source 310. To provide this tracking function, the detection circuit comprises a mixer 325 which has a direct connection to the transmission line 6 and to which is also connected a local oscillator 326 which generates a 10.7 MHz signal. As is conventional, the mixer 325 outputs the difference signal generated by mixing the excitation signals with the signal from the local oscillator 326 and feeds this to a SAW filter 327. The SAW filter 327 therefore receives a signal which is at around 190 MHz. The SAW filter 327 is arranged to clean up the output of the mixer 325 and the output of the SAW filter 327 is fed to an amplifier 328. The output of the amplifier 328 is fed to a mixer 322a provided in the receiver 322. The mixer 322a mixes the signal received via the directional coupler 321 (ie the signal detected by the SAW devices 1) with the output from the amplifier 328 which has a frequency of around 190 MHz and which follows the frequency of the excitation signals. When these two signals are mixed in the mixer 322a in the receiver 322, the difference signal is taken as the output from the mixer 322a. The component of the detected signal which has a frequency which matches the excitation signal will give rise to an intermediate frequency signal having a frequency of 10.7 MHz at the output of the mixer 322a. This is a consequence of mixing the received signal with the signal output by the amplifier 328 which will always be 10.7 MHz less than the frequency of the excitation signal applied to the transmission line 6 and mixed in the mixer 325. The output of the mixer 322a in the receiver 322 is fed to an intermediate frequency filter which is centred on 10.7 MHz and has a bandwidth of about 100 KHz. The bandwidth of the filter is preferably chosen taking the sweep rate into account. Generally a small bandwidth improves performance but if it is too small distortion can occur—preferably the bandwidth is optimised for the chosen sweep rate. This filter thus serves to filter out elements of the detected signal which do not correspond to the currently applied excitation signal. This has the advantage of filtering out noise and also filtering out signals from SAW devices which may be caused to resonate by an excitation signal having a resonant frequency somewhat removed from the excitation signal or signals from a SAW device 1 which is still resonating having recently been driven by an excitation signal which matched its resonant frequency.

The receiver 322 in conjunction with the mixer 325, local oscillator 326, SAW filter 327 and amplifier 328 can together be considered to comprise a tracking receiver. The provision of such a tracking receiver can help dramatically in the practical implementation of the system of the present kind.

The filtered output from the receiver 322 is a radio frequency signal and the envelope of the signal is converted into a low frequency signal by the power detector 323. This low frequency signal represents the amplitude of the detected signal and is fed to the trigger circuit 324.

At a general level it can be said that the trigger circuit 324 determines from this low frequency signal whether the frequency of the applied excitation signal, at that point in time, is representative of the resonant frequency of one of the SAW devices 1 by determining whether there is a minimum in amplitude of received signal at that point.

There are different possible implementations for the trigger circuit 324. A first implementation, which is that of the present embodiment, will now be described with reference to FIG. 3.

In this embodiment the trigger circuit comprises two comparators each having a latch gate. A first of the comparators 3241 has its inverting input connected to the input to the trigger circuit 324 and its non-inverting input connected to a potentiometer 3242, the latch gate of this first comparator 3241 is connected to a voltage source, and the output of this first comparator 3241 is connected to the latch gate of the second comparator 3243. The inverting input of this second comparator 3243 is again connected to the input to the trigger circuit 324 whilst the non-inverting input is connected via a resistor R1 to the inverting input and a capacitor C1 to ground. This arrangement provides two main functions. First of all the arrangement of the first comparator 3241 and the potentiometer 3242 allows a latch threshold to be set. Once this threshold is set, the first comparator 3241 will remain with its output state low whilst the input signal received by the trigger circuit 324 has not reached the threshold value. Whilst in this state the second comparator 3243 is essentially switched off. This means that small drops in the amplitude of the signal received by the directional coupler 321 (and appropriately processed on to the trigger circuit 324) due to other factors than resonance having been found, will not trigger the trigger circuit 324 (unless of course these other factors lead to a drop in amplitude which exceeds the threshold). Once the threshold condition has been satisfied however, the first comparator 3241 flips to a high state which arms the second comparator 3243 to perform its function.

Once the second comparator 3243 has been armed its output state flips to high and this means there will be a signal on the output of the trigger circuit 324.

The arrangement of the resistor R1 and capacitor C1 with the second comparator 3243 has the effect that the signal seen by the non-inverting input of the second comparator 3243 follows, with a delay, the signal seen by the inverting input.

Because the signal seen by the non-inverting input always follows with some delay, the signal seen by the inverting input, whilst a signal is failing in value (eg going more negative), the signal seen by the inverting input will always be lower, (i.e. in the present case, more negative) than that seen by the non-inverting input. However, as a valley point (minimum) is reached and the signal starts increasing (in the present case becoming less negative) the signal on the non-inverting will still trail that on the inverting input but this now means that the signal on the non-inverting input is lower (i.e. more negative) than that on the inverting input. This means that as a minimum in amplitude passes, the state of the second comparator 3243 will flip. In the present case that means that the output of the second comparator 3243 will go from high to low and this will give rise to a falling edge on the output of the trigger circuit 324.

In the present embodiment the output of the trigger circuit 324 is connected to an input of the DSP 311 and a falling edge on that signal acts as an interrupt signal to the DSP 311 which serves to indicate that the trigger circuit 324 has made a determination that the frequency of the excitation signal then being applied to the transmission line 6 is representative of the resonant frequency of one of the SAW devices 1.

By reference to FIG. 4 the effect of this triggering process 324 may be more clearly appreciated. On the lefthand side of FIG. 4 the situation is shown where a minimum in received amplitude is detected around the resonant frequency of the first of the SAW devices 1. In the diagram shown in FIG. 4, the uppermost plot diagrammatically shows the excitation signals applied to the transmission line 6—there being a continuous frequency stepped signal with a 180 Hz difference in frequency between each step. The middle plot shows the value of the received amplitude signal as output by the power detector 323 and the bottom plot shows the output of the trigger circuit 324. Thus it will be seen that the output of the trigger circuit 324 goes high at a point when the output of the power detector 323 falls to such a level that the threshold condition determined by the potentiometer 3242 and first comparator 3241 is met and remains high until the valley point (minimum) of the received signal is detected by the trigger circuit 324. The output of the trigger circuit 324 then remains low until the resonant frequency of the second SAW device is approached, as shown in the right hand half of the diagram.

The excitation signals as applied to the transmission line 6 in this case again can be seen in the top plot, with the output of the power detector 323 being shown in the middle plot, and the output of the trigger circuit 324 being shown in the bottom plot.

It will be appreciated that in the most simple implementation mentioned above, between the two parts of the plot shown in FIG. 4, the excitation signals continue to be applied across the whole frequency range with the output of the power detector remaining fairly constant at its upper limit as shown in FIG. 4 and the output of the trigger circuit remaining low. However, in a more sophisticated scheme, the gap between the two plots shown in FIG. 4 may in fact consist of the electrical energy source 310 jumping directly from the end of one plot to the start of the other.

As the DSP 311 receives the interrupt signals in respect of the detection of both these valley points, it outputs appropriate signals to the analysing apparatus 5 to allow determination of the desired physical quantities making use of the information concerning frequencies considered to be representative of the resonant frequency of the two SAW devices 1. Again it would be possible, in the conventional way, to use the difference in resonant frequency between the two SAW devices 1 as the means for determining applied torque and the sum of the resonant frequencies might be used to determine temperature.

It should of course be appreciated that the motivation behind the present techniques is to develop more accurate interrogation equipment and develop simple detecting and triggering methods for identifying the resonant frequency of SAW devices 1 so that the cost and size of the interrogation equipment may be minimised. In some ways the trigger circuit 324 described above may be considered crude but it is considered advantageous that simplicity is achieved.

Other forms of triggering may be used. One disadvantage with the method described above is that the amplitude signals detected using the above type of technique give rise to relatively shallow and wide dips in amplitude around resonance, and due to noise, the bottom of the valley may be relatively flat and/or misleading. This can reduce resolution and/or accuracy.

One alternative approach is to make use of curve fitting techniques in order to determine the frequency which best represents the resonant frequency of the respective SAW 1 at that point in time. One such curve fitting algorithm is schematically shown in FIG. 5. Here the idea is to detect the frequency at which the amplitude of the received signal passes first and second triggering levels T1 and T2 as shown in FIG. 5 on both sides of the minimum. Then fit a straight line to these points and take the point where these two straight lines cross, designated as P in FIG. 5, and determine that the frequency on the plot which this point P represents, is the frequency which best represents the resonant frequency of the respective SAW device. Again whilst this is a relatively simple algorithm. the attraction is in terms of simplicity and speed of processing. More complicated curve fitting methods could be used but in general terms there will be a trade off in terms of response time or the expense of the equipment which must be provided.

Yet another method for making a decision that an applied signal is representative of the resonant frequency of one of the SAW devices is to make use of a Kalman filter. The use of a Kalman filter is a known mathematical technique which provides an efficient computational (recursive) means to estimate the state of a process in a way that minimises the mean of the squared error. The idea of the filter is to use linear stochastic difference equations to predict displacement of the curve of a known shape.

FIG. 6 shows an alternative interrogation apparatus which may be used in the physical quantity measuring apparatus of FIG. 1. This interrogation apparatus 3 is also connected to a plurality of SAW devices 1 via a transmission line 6 in the same way as the interrogation apparatus described above in relation to FIG. 2.

At the most general level, the structure and operation of the interrogation circuit 3 shown in FIG. 6 is the same as that shown in FIG. 2. That is to say, the interrogation circuit 3 comprises an RF electrical energy source 310 (which is shown in less detail in FIG. 6 than in FIG. 2 but which is substantially the same as the electrical energy source shown in FIG. 2) which is connected via the transmission line 6 including a rotary couple 4, to the SAW devices 1. Again a detection circuit 320 is provided for sensing signals detected back along the transmission line 6 by the SAW devices 1. Further, again, in this embodiment, the detection circuit 320 comprises a directional RF coupler 321 with its forward port connected to ground and its reflection port serving as the supply to the remainder of the detection circuit.

The operation of the electrical energy source 310 is generally the same as that described above in relation to FIGS. 2 to 4 and the function of the detection circuit 320 is also broadly the same in that it is arranged to indicate when the frequency of an applied excitation signal is representative of the resonant frequency of one of the SAW devices 1. Again, as in the embodiment described above in relation to FIGS. 2 to 4, this indicator signal is in the form of an interrupt signal which is returned to the digital signal processor of the electrical energy source 310.

In the interrogation apparatus 3 shown in FIG. 6 however, the detection of a resonance point is carried out by monitoring the phase of the received detected signals.

The reflection port of the directional coupler 321 is connected to an RF amplifier 1001 and the output of this RF amplifier 1001 is fed into a phase correction circuit 1002. The phase correction circuit 1002 is provided to correct any phase delay which is introduced due to cable lengths etc. The output of the phase correction circuit 1002 is connected to a power splitter 1003 which has one output connected to a first mixer 1004 and another output connected to a second mixer 1005. A second power splitter 1006, connected to the output of the electrical energy source 310, has one output connected to the first mixer 1004 and a the second output connected to a 90° phase shift circuit 1007. The output of the 90° phase shift circuit 1007 is connected to the second mixer 1005. The effect of this arrangement is to allow the incoming detected signal, after amplification and phase correction to be mixed with the excitation signal in the first mixer 1004 and mixed with the excitation signal phase shifted by a 90° phase shift in the second mixer 1005. Thus the output of the first mixer 1004 is an “in phase” signal (I) and the output of the second mixer 1005 is a “quadrature phase” signal (Q). These output signals are both DC levels which in the present embodiment have an amplitude of around 200 mV (a diode ring double balanced mixer being used for the first and second mixers 1004 and 1005). The outputs of the two mixers 1004 and 1005 are fed into a comparator 1008 and the output of this comparator 1008 forms the output of the interrogation circuit 3 and is thus connected back to the controllable electrical energy source 310.

As will be explained in more detail below, by comparing the in phase and quadrature signals, the comparator 1008 is able to output a signal which is indicative of resonance of one of the SAW devices 1 having been found.

However, in order to limit the instance of false detections of resonant frequencies, the detection circuit 320 also includes an arming circuit 1010 which is arranged to arm the comparator 1008 only if an amplitude threshold condition is satisfied. In the present embodiment, the arming circuit 1010 comprises a log amplifier 1010a, which provides good amplification characteristics across a broad range of frequencies, and an amplitude trigger circuit 1010b which is connected to the output of the log amplifier 1010a. The amplitude trigger circuit 1010b is arranged to enable the comparator 1008 when the detected amplitude reaches a predetermined threshold. This makes use of the idea that in the region of resonance there will be a marked decrease in amplitude in the detected signal. Whilst this decrease in amplitude is perhaps too shallow and too broad to allow a very accurate determination of the resonant frequency simply by looking for the minimum point of this decrease in amplitude, it is certainly good enough to give a preliminary indication that resonance is being approached and thus it is appropriate for use in arming the comparator 1008, which is acting as the decision means deciding if an applied excitation signal has a frequency which is representative of a resonant frequency of one of the SAW devices 1. The operation of the interrogation circuit shown in FIG. 6 is described below in greater detail with reference to FIG. 7.

FIG. 7 shows plots which are similar to those shown in FIG. 4 and described above. Thus the uppermost plot represents the output of the controllable RF electrical energy source 310 and again in this case an excitation signal changing in frequency in steps of 180 Hz is applied to the SAW devices 1 via the transmission line 6. In the second plot the amplitude of the received signals as seen by the amplitude trigger circuit 1010b are shown. In the middle plot the enabled signal generated by the trigger circuit 1010 is shown. In the second to bottom plot the in phase (I) and quadrature (Q) signals fed into the comparator 1008 are shown. In the bottommost plot the output of the comparator 1008 is shown. On the lefthand side of the diagram these different traces are shown in respect of the signals around the resonant frequency of a first of the SAW devices 1 and on the righthand side of the diagram the corresponding signals are shown in respect of a second of these SAW devices 1.

Looking at the second and third plots from the top of FIG. 7 it can be seen that when the received amplitude signal falls below a trigger threshold T_{A} set by the amplitude trigger circuit 1010b, the trigger circuit 1010 outputs an enable signal (as illustrated in the third plot) and this signal is fed to the comparator 1008. During the time that the signal in the third plot from the top is high, the comparator 1008 is enabled and is arranged to go high and therefore generate an output once this enable signal is received. This rising edge is shown in the bottommost plot in FIG. 7.

It is a general characteristic of resonating structures such as SAW devices, used in the current techniques, that a phase transition in reflected signal will occur as the resonating structure is taken through its resonant frequency. In particular with a SAW device, prior to reaching its resonant frequency the signal reflected by the SAW device will lag the excitation signal whilst once the excitation signal has a higher frequency than the resonant frequency of the SAW device, the reflected signal will lead the excitation signal.

What is important to the present technique is that due to this phase transition at resonance, at some point the in phase signal (I) will cross with the quadrature signal (Q) and this crossing point will cause the comparator 1008 to flip. In this case the comparator will flip from a high state to a low state. This crossing point C is indicated in the second bottom plot in FIG. 7.

It can also be seen that the output of the comparator goes low as this crossing point C is reached.

Again as in the case described above in relation to FIG. 2, this falling edge of the comparator 1008 output signal can be used as an interrupt by the controllable electrical energy source 310.

It may be noted that this crossing point C does not occur precisely at the resonant frequency of the SAW device 1 but it is in a fairly stably fixed relation to the resonant frequency of the SAW device 1. Moreover the use of the crossing point gives rise to a particularly simple way of determining a frequency which is representative of the resonant frequency of the SAW device 1 which helps to allow the provision of smaller and cheaper interrogation apparatus. The fact that the crossing point C is offset from the resonant frequency of the SAW device 1 may be taken into account in a number of ways. For example, during calibration this offset may be taken into account on a theoretical and/or empirical basis and moreover, in at least some techniques, it is the difference between resonant frequencies of the SAW devices 1 which is important and therefore because the spacing between these crossing points C will be equal to the spacing between the resonant frequencies, the result of looking at the frequency difference between the crossing points C is for practical purposes the same as looking at the frequency difference between the actual points of resonance.

In general terms the phase detection method should give rise to more accurate results than an amplitude method because of the relatively wide and shallow amplitude response which the SAW devices 1 give. On the other hand, without the amplitude arming trigger, all manner of different types of phase transition might be detected by the comparator 1008 and give false readings.

FIG. 8 shows an alternative arming circuit 1010′ which may be used in place of the arming circuit 1010 shown in FIG. 6. Note A and Note B in FIG. 6 show pick up points for the alternative arming circuit 1010′ shown in FIG. 8. The alternative arming circuit 1010′ is similar in structure and operation to the tracking receiver described above in relation to FIG. 2. Thus, the alternative arming circuit 1010′ comprises an RF receiver 1322 which is connected to the reflection port of the directional coupler 321 and which has an output connected to a power detector 1323 which in turn is connected to a trigger circuit 1324. Moreover, there is provided a mixer 1325 which is connected to the output of the controllable electrical energy source 310 and a local oscillator 1326. The output of the mixer 1325 is connected to a SAW filter 1327 and on to an amplifier 1328. This amplifier 1328 in turn is connected to a mixer 1322a in the receiver 1322, this mixer 1322a in the receiver 1322 receives the detected signal from the directional coupler 321. The output of the mixer 1322a, in the receiver 1322, is fed to an intermediate frequency filter 1322b. The arrangement and functioning of all the components shown in FIG. 8 besides the trigger circuit 1324 are the same as those shown in FIG. 2 and described with reference thereto. Therefore a detailed description of the operation of these components is omitted at this point for brevity. Suffice it to say that the combined effect of these components is to filter out signals not within a relatively narrow band of frequencies around the excitation frequency then being applied to the transmission line 6. Therefore the output of the power detector circuit 1323 is an amplitude signal which is indicative of the amplitude of the reflected signal having frequencies in the region of the applied excitation signal. This amplitude signal is fed into the trigger circuit 1324 which in this case consists of a simple amplitude trigger having the same function as the amplitude trigger 110b described above. The trigger circuit 1324 is thus arranged so that whilst the received amplitude signal remains on one side of the threshold the output is zero but once the threshold is passed, an output signal is generated by the trigger circuit 1324 which serves to arm the comparator 1008 in the detection circuit 320. The inclusion of this more sophisticated arming circuit 1010′ will lead to a more reliable arming operation in that anomalous decreases in reflected amplitude, which are away from the frequency of the excitation signal at that point in time, are less likely to give rise to unwarranted arming of the comparator 1008. It should be said however, that for many practical implementations, the simpler arming circuit 1010 shown in FIG. 6 is quite sufficient.

As alluded to above rather than using a direct rotary coupler 4 in the transmission line 6 for any of the above techniques, in some instances it may be preferable to use antennas on both sides of a free space link. If antennas are used then the sensitivity of the detection circuits and, in particular for example, the radio receiver 322 will need to be increased to accommodate the additional path loss which will be experienced by a wireless connection. Similarly, the more complex arming circuit 1010′ shown in FIG. 8 may be of more significant benefit in a wireless signalling implementation.

As yet a further alternative in the case of phase measurement, an output from the arming circuit 1010 may be fed to the phase correction circuit 1002 to help align the phase seen by the first and second mixers 1004, 1005. In particular this technique might be used to apply a phase shift to the signals which is such as to bring the crossover point between the (I) and (Q) signals closer to the actual resonant frequency of the SAW device. This has the advantage of bringing the (I) and (Q) signals into the more linear part of the waveform.

Whilst the use of SAW devices has been extensively mentioned in the present specification it should be recognised that other acoustic devices may be used, which for example, utilise Lamb waves, Love waves and bulk waves. Furthermore, other resonant structures may be used such as amorphous wire. It is preferable that any resonant structure used is a high Q resonant device.

It should also be mentioned that whilst use of a directional coupler for picking up signals from the transmission line 6 is used in the embodiment above any other suitable technique for detecting the reflected signal can be used in methods and apparatus described in this specification. Moreover, in at least some cases monitoring of the forward signal on the transmission line may be carried out and the thus detected signal processed in the same or a similar way to that described above to identify resonance.

It will be appreciated that the circuits, modules, etc described above may be implemented using discrete components and/or using one or more application specific integrated circuits (ASICs).

1-41. (canceled)

42. Apparatus for use in measuring the value of at least one physical quantity, the apparatus comprising at least one electrically resonant structure, the resonant frequency of which is affected by said physical quantity, an electrical energy source, and a transmission line connecting the source to the resonant structure, wherein the electrical energy source is arranged to provide excitation signals to the electrically resonant structure via the transmission line and is controllable so as to vary the frequency of applied excitation signals, the apparatus further comprising a detecting module for monitoring signals on the transmission line following application of excitation signals, the detecting module being arranged to output an indicator signal if a frequency is determined, from monitoring the detected signal, to be representative of the then current resonant frequency of the electrically resonant structure.

43. Apparatus according to claim 42 in which the detecting module comprises a tracking tuned receiver which is arranged to track the frequency of the applied excitation signals, wherein the detecting module comprises a decision module for deciding whether a frequency of an applied excitation signal is representative of the then current resonant frequency of the resonant structure,
the detecting module comprises an arming module for controllably arming the decision module such as to enable decision making;
and the detecting module is arranged for monitoring reflected signals returned along the transmission line from the resonant structure, and is arranged for detecting the phase of the reflected signal,
the decision module being arranged to monitor the phase of the reflected signal to decide whether a frequency of an applied excitation signal is representative of the then current resonant frequency of the resonant structure, and the arming module being arranged to arm the decision module to enable such a decision only if a predetermined amplitude threshold condition is satisfied.

44. Apparatus according to claim 42 in which the detecting module comprises a tracking tuned receiver which is arranged to track the frequency of the applied excitation signals.

45. Apparatus according to claim 44 in which the tracking tuned receiver is at least one of: disposed physically close to and is directly electrically connected to the electrical energy source.

46. Apparatus according to claim 42 in which the detecting module comprises one of: a decision module for deciding whether a frequency of an applied excitation signal is representative of the then current resonant frequency of the resonant structure, and a calculation module for calculating a frequency which is representative of the then current resonant frequency.

47. Apparatus according to claim 46 in which the detecting module comprises an arming module for controllably arming the one of a decision module and a calculation module such as to enable one of decision making and calculation.

48. Apparatus according to claim 47 in which the arming module is arranged to detect the amplitude of the detected signal and arm the one of a decision means and a calculation means if a predetermined amplitude threshold condition is satisfied.

49. Apparatus according to claim 48 in which the arming module is arranged to inhibit operation of the one of a decision module and a calculation module when the applied signal is not in a frequency range corresponding to the resonant structure response.

50. Apparatus according to claim 43 in which the arming module is arranged to inhibit operation of the one of a decision module and a calculation module when the applied signal is not in a frequency range corresponding to the resonant structure response.

51. Apparatus according to claim 42 in which the detecting module is arranged for detecting the amplitude of the detected signal.

52. Apparatus according to claim 43 in which the detecting module is arranged to generate an in phase signal using the reflected signal and a quadrature phase signal using the reflected signal, the decision module being arranged for comparing the quadrature phase signal with the in phase signal in determining whether a frequency of an applied excitation signal is representative of the then current resonant frequency of the resonant structure.

53. Apparatus according to claim 52 in which the decision module is arranged to determine that a frequency of an applied excitation signal is representative of the then current resonant frequency of the resonant structure when the frequency of the applied excitation signal is such that it is detected that the quadrature phase signal crosses with the in phase signal.

54. Apparatus according to claim 46 in which the at least one of a decision module and a calculation module is arranged to identify a turning point in the amplitude of the detected signal as the frequency of applied excitation signals is varied.

55. Apparatus according to claim 46 in which the one of a decision module and a calculation module is arranged to perform a curve fitting operation on the detected signal as the frequency of applied excitation signals is changed in order to determine when a frequency of an applied excitation signal is representative of the then current resonant frequency of the resonant structure.

56. Apparatus according to claim 42 in which a Kalman filter is used in determining whether a frequency of an applied excitation signal is representative of the then current resonant frequency.

57. Apparatus according to claim 42 in which the electrical energy source is arranged to frequency sweep the excitation signals.

58. Apparatus according to claim 57 in which the apparatus is arranged to apply excitation signals by sweeping the frequency of the signals over at least one selected range of frequencies around a trial resonant frequency of at least one resonant structure.

59. Apparatus according to claim 58 in which the apparatus is arranged to set a trial resonant frequency equal to at least one of:
the default resonant frequency;
the resonant frequency for that resonant structure as last detected;
a value calculated taking into account at least one of the measured resonant frequency of another resonant structure which has been more recently determined and the value of the default resonant frequency.

60. Apparatus according to claim 58 in which the energy source is arranged so that the amplitude of the applied signals at the start of each range is reduced relative to the average amplitude.

61. A physical quantity measuring apparatus comprising an apparatus for use in measuring the value of at least one physical quantity according to claim 42 and an analyzing module for determining the value of a physical quantity in dependence on the output of the apparatus for use in measuring the value of at least one physical quantity.

62. A method of using an apparatus in measuring the value of at least one physical quantity, the apparatus comprising at least one electrically resonant structure, the resonant frequency of which is affected by said physical quantity, an electrical energy source, and a transmission line connecting the source to the resonant structure, and the method comprising the steps of:
using the electrical energy source to provide excitation signals to the electrically resonant structure via the transmission line and controllably varying the frequency of applied excitation signals;
monitoring signals on the transmission line following application of excitation signals; and outputting an indicator signal if a frequency is determined to be representative of the then current resonant frequency of the electrically resonant structure.

63. Apparatus for use in measuring the value of at least one physical quantity, the apparatus comprising at least one electrically resonant structure, the resonant frequency of which is affected by said physical quantity, an electrical energy source, and a transmission line connecting the source to the resonant structure, wherein the electrical energy source is arranged to provide excitation signals to the electrically resonant structure via the transmission line and is controllable so as to vary the frequency of applied excitation signals, the apparatus further comprising a detection module for monitoring reflected signals returned along the transmission line from the resonant structure following application of excitation signals, the detection module being arranged to output an indicator signal if it is determined from monitoring the returned signal that a frequency of an applied excitation signal is representative of the then current resonant frequency of the electrically resonant structure, and wherein the detection module is arranged to generate an in phase signal using the reflected signal and a quadrature phase signal using the reflected signal, the detection module comprises a decision module for deciding whether the frequency of the applied excitation signal is representative of the then current resonant frequency of the electrically resonant structure, and the decision module is arranged for comparing the quadrature phase signal with the in phase signal and arranged to determine that a frequency of an applied excitation signal is representative of the then current resonant frequency of the resonant structure when the frequency of the applied excitation signal is such that it is detected that the quadrature phase signal crosses with the in phase signal.

64. Apparatus for use in measuring the value of at least one physical quantity, the apparatus comprising at least one electrically resonant structure, the resonant frequency of which is affected by said physical quantity, an electrical energy source, and a transmission line connecting the source to the resonant structure, wherein the electrical energy source is arranged to provide excitation signals to the electrically resonant structure via the transmission line and is controllable so as to vary the frequency of applied excitation signals, the apparatus further comprising a detection module for monitoring reflected signals returned along the transmission line from the resonant structure following application of excitation signals, the detection module being arranged to output an indicator signal if a frequency is determined, from monitoring the returned signal, to be representative of the then current resonant frequency of the electrically resonant structure, and wherein the detection module comprises a tracking tuned receiver which is arranged to track the frequency of the applied excitation signals.

65. Apparatus according to claim 42 in which the resonant structure comprises an acoustic wave device.

66. Apparatus according to claim 42 in which the resonant structure comprises amorphous wire.
